(19) United States
(12) Patent Application Publication
(10) Pub. No.: US 2019/0093841 A1
(43) Pub. Date: Mar. 28, 2019

(54) Solar Tube

(71) Applicant: Mark Fuller, Sun Valley, CA (US)

(72) Inventor: Mark Fuller, Sun Valley, CA (US)

(21) Appl. No.: 16/142,718

(22) Filed: Sep. 26, 2018

Related U.S. Application Data
(60) Provisional application No. 62/563,598, filed on Sep. 26, 2017.

(51) Int. Cl. F21S 19/00; F21S 9/03; H01L 31/054; H02S 40/38

(52) U.S. Cl. CPC F21S 19/005; F21S 9/037; H02S 40/38; H01L 31/0547; H01L 31/0543

(57) ABSTRACT

A light source generally comprising a light tube configured with artificial light sources and sustainable sources of energy is disclosed. The light source may provide natural light during daylight hours, and a combination of natural light and artificial light, or only artificial light during hours when natural light is diminished or not available. The resultant light output may be constant and the artificial light may be powered by sustainable energy sources such as solar panels and rechargeable batteries.

### CROSS-REFERENCE TO RELATED APPLICATION

This application claims the benefit of U.S. Provisional Application No. 62/563,598, filed Sep. 26, 2017, the contents of which are incorporated herein by reference.

### FIELD OF THE INVENTION

The current invention generally relates to sources of light, including light tubes that involve solar light, artificial light and/or sustainable energy sources.

### BACKGROUND OF THE INVENTION

Skylights, light tubes and other types of windows that allow sunlight to enter into indoor spaces or other areas have existed for some time. The benefits of these types of sources of natural light is that they may provide enough light during daylight hours to reduce the need for artificial light and thus reduce power consumption.

In addition, these types of sources of natural light may provide a healthy ambiance to workers in an office, patrons at a restaurant, or to the family in the living room of their home. For this reason, these sources of natural light are highly desirable.

However, during hours of the day when natural light is not available, for example in the early morning or the evening, these sources of natural light do not provide sufficient or any light. In addition, the same may be true during weather conditions such as cloudy or rainy days. And so, during these times it is necessary to employ sources of artificial lighting such as ceiling lights.

The cost of purchasing and installing skylights may be quite expensive and cumbersome. Holes need to be cut in the roof and the ceiling, and the units need to be installed and weatherproofed. Given this, the appeal of purchasing and installing these units is diminished by the cost and the need to clutter the ceilings with both traditional light fixtures in addition to these solar units.

As such, there is a need for a source of light that may provide both natural light when it is available and artificial light when it is not. In addition, there is a need to provide both natural light and artificial light in a compact unit that does not take up excess space on the ceiling or roof or other location.

In addition, it can be seen that with traditional skylights and other sources of natural light, when the natural light begins to wane, the artificial lights need to be turned on. And once they are, they may provide a different intensity of light than the prior natural light, and that this may uncomfortable and/or disruptive to the workplace, restaurant or other space utilizing the lights. As such, there is also a need for a light source to provide a constant or generally consistent output regardless of whether it is providing natural or artificial light.

### SUMMARY OF THE INVENTION

In a first aspect of the invention, a light source is described that may include a source of natural light and a source of artificial light. The light source may generally include a physical structure such as a light pipe that may collect natural sunlight from a position above a roof/ceiling, or otherwise on the exterior, of a structure and guide it into the space below. The light source may also include a source of artificial light that it may employ when natural light is not available. An electronics assembly may also be provided to control and provide power to the artificial light source. In addition, sources of power may also be provided to power the artificial light source.

In another aspect of the invention, the light pipe may include a dome at the top input to collect the light, reflective inner walls to guide the light down through the tube, and a diffuser at the bottom end to diffuse the light into the interior area.

In another aspect of the invention, the light tube may include bends.

In another aspect of the invention, the light tube may include a base that may configure the bottom end of the light tube to the bottom surface of the ceiling.

In another aspect of the invention, the light source may include artificial light sources that may be configured with the base of the light tube.

In yet another aspect of the invention, the artificial light sources may include LEDs and a lens.

In another aspect of the invention, the lens may extend through the wall and into the inner portion of the base to provide artificial light into the light tube.

In another aspect of the invention, the lens may have a cleaved end at an angle so that the output light may refract and emit at an angle with respect to the axis. The lens may be oriented such that the refracted output light may be directed downward into the light tube so that it may be released out the base.

In another aspect of the invention, the artificial light source may include a heat sink to draw heat away from the LEDs and to dissipate it to the outside environment.

In another aspect of the invention, the light source may include an electronics assembly that may include electrical and non-electrical components necessary to control, power and generally affect the LEDs.

In another aspect of the invention, the light source may include a light sensor that may measure the amount of light passing through the light tube to allow the LEDs to be adjusted to keep the emitted light constant. This may be necessary when natural light wanes at the end of the day or during adverse weather conditions.

In another aspect of the invention, the light source may include a source of power to power its artificial light sources. Such source(s) of power may include a solar panel, a wind turbine, or other source of power. The light source may also receive electrical power from the local power grid.

In yet another aspect of the invention, the light source may include rechargeable battery packs that may be charged by the source of power so that the batteries may provide power to the artificial sources of light when required.

In another aspect of the invention, the source of power may be solar panels that may include photovoltaic cells that may absorb sunlight, transform it into electricity and provide it to the battery pack for charging.

In another aspect of the invention, the light sensor and the artificial sources of light may be calibrated together so that the light source may provide near-constant and/or generally consistent light intensity during variations of natural light.

Other aspects of the invention are discussed herein.

### BRIEF DESCRIPTION OF THE DRAWINGS

FIG. 1 is a side view of a light pipe.

FIG. 2 is a perspective view of a base of a light pipe.

FIG. 3A is a perspective expanded view of a light engine.

FIG. 3B is a side view of a lens.

FIG. 3C is a bottom view of a lens.

FIG. 3D is a perspective view of a light engine.

FIG. 4 is a bottom view of the base of a light tube.

FIG. 5 is a perspective view of the base of a light tube.

FIG. 6 is a perspective view of a base of a light tube.

FIG. 7 is a top view of a LED holder.

FIG. 8 is a top view of a solar panel.

### DETAILED DESCRIPTION OF THE PREFERRED EMBODIMENTS

The following detailed description is not intended to limit the current invention. Alternate embodiments and variations of the subject matter described herein will be apparent to those skilled in the art.

The light source 10 of the current invention and the benefits it may provide are now described with reference to the figures. Where the same or similar components appear in more than one figure, they are identified by the same or similar reference numerals.

In general, light source 10 provides lighting to an area by channeling natural sunlight during daylight hours and by providing artificial light during non-daylight hours. In addition, light source 10 may include sustainable sources of power such as solar power, wind power or other sources of power that may charge or otherwise provide light assembly 10 any power required to provide artificial light when required.

Light source 10 may be installed inside office spaces, living spaces, hotels, restaurants, public buildings or in atriums, lobbies or other indoor locations. Display 10 may also be installed in outdoor spaces such as outdoor shelters, amusement areas, outdoor dining or bars, poolside cabanas or in other types of outdoor spaces. As such, light source 10 may provide an attraction to these buildings and spaces. Light source 10 may also be included in water and lighting displays to provide enhanced visual effects.

As shown in the figures, light source 10 may include light tube assembly 100, light engine assembly 200, electronics assembly 300 and energy source assembly 400. Additional components and/or assemblies may also be included as described in later sections. In general, once installed in the ceiling/roof, wall or other location of a building or structure, light source 10 may provide natural light to the area below it via light tube assembly 100, and artificial light via light engine assembly 200 during times when natural light may not be available (for example, during nighttime hours). Light emitted by light engine assembly 200 may be seamlessly lensed into light tube assembly 100 so that as the natural light provided by the sun fades as the day transitions into night, light emitted from light engine 200 may gradually increase so that the overall light provided by light source 10 may be near-constant or otherwise generally consistent.

Electronics assembly 300 may include the power and control electronics to the light engine assembly 200, and energy source 400 may include sources of power that may provide power to the light engine assembly 200 as necessary. In one example, energy source 400 may include at least one rechargeable battery and at least one photovoltaic cell that may receive sunlight during the day to charge the battery. In this way, the charged battery may be used during the non-daylight hours to provide power to the light engine assembly 200 to be used to provide artificial light.

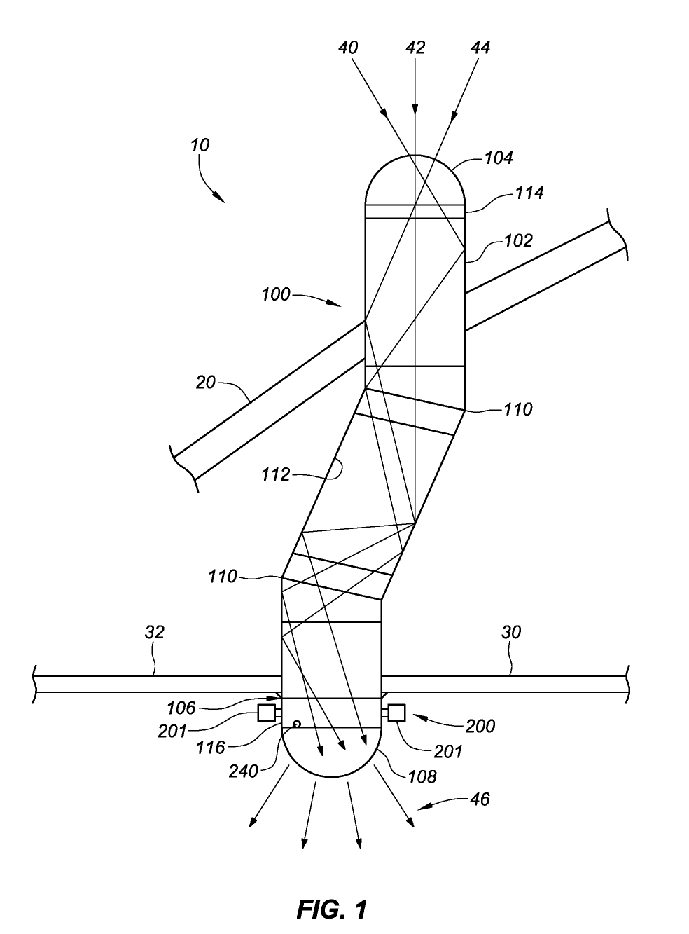

Referring now to FIG. 1, light tube assembly 100 will be described in further detail. Light tube assembly 100 may include a physical structure like a tube 102 or pipe, or other type of optical waveguide that may be used to transport or distribute light from one area to another. In practical use, light tube assembly 100 may comprise a tube 102 with a highly reflective inner surface 112 such that light rays 40, 42, 44 that enter one end of the tube 102 may be guided through the tube 102 and out the other end. Note that light rays 40, 42, 44 are shown for demonstrational purposes and may represent light that may enter light tube assembly 100 at different times of day. For example, light ray 40 may represent light that may enter the light tube 102 in the morning hours, light ray 42 may represent light that may enter the light tube 102 around mid-day, and light ray 44 may represent light that may enter the light tube 102 in the later hours of the day.

It can be seen, however, that many different light rays may enter light tube 102 during daylight hours. The reflectivity coefficient of the inner reflective walls 112 may preferably be very high (for example, greater than 99%) such that the intensity of the light rays 40, 42, 44 is not diminished, degraded or otherwise lost as the light travels through the tube 102. In addition, the diameter of light tube 102 may be as little as 1.0 cm or less and as large as 1.0 m or more.

As depicted in FIG. 1, light tube assembly 100 may be installed in the roof 20 and ceiling 30 of a building or structure, so that it may pass from outside above the roof 20 to inside beneath the ceiling 30. Alternatively, light tube assembly 100 may be installed in walls or other exterior/interior locations. In this way, it may guide light rays 40, 42, 44 from outside the building to the inside.

The top end of tube 102 may include a dome 104 that may serve to collect and/or reflect as much sunlight as possible into the tube 102. Dome 104 may comprise a transparent material such as acrylic, ABS, Polycarbonate, glass or other type of material and may also provide protection to the light tube assembly 100 from adverse conditions such as extreme weather, rain, hail, etc.

Dome 104 may also include other types of structures to collect the sunlight such as directional collectors, reflectors, Fresnel lens devices or other types of components that may assist in collecting light into the tube 102. In addition, light tube assembly 100 may also include a storm collar 114 to provide a water proof seal between the tube 102 and the dome 104, as well as other weather proofing elements such as flashing between the tube 102 and the roofing, caulking around any seams, etc.

As the tube 102 transitions from above and through the roof 20 and through any space that may separate the roof 20 and the ceiling 30 (such as an attic or other type of space), the tube 102 may need to include bends 110 that may be used to reposition the passageway of the tube 102 to deliver light rays 40, 42, 44 to the desired location in the ceiling. Note that any number of bends 110 may be used but it may be preferable to keep the bends 110 to a minimum to minimize any loss of light intensity. Once in position, the tube 102 may then pass through the ceiling 30 to deliver the light into the area below.

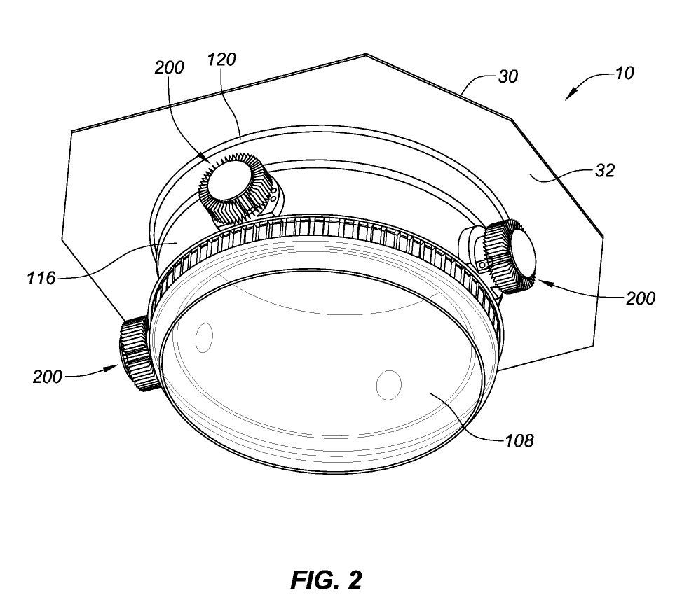

Light tube assembly 100 may include ceiling frame 106 that may serve to secure light tube 102 as it passes through the ceiling 30. Ceiling frame 106 may include a mount or other type of structure that may or may not extend through ceiling 30 and that may brace or otherwise support light tube 102. In addition, light tube assembly 100 may include base section 116 that may encircle and generally be configured with the bottom end of light tube 102. Base 116 may also provide a seal 120 between the bottom end of light tube 102 and the underneath side surface 32 of ceiling 30 (best seen in FIG. 2). In this way, base 116 may represent the bottom end of light tube 102.

Base section 116 may include a diffuser 108 that may be generally located at the output of base section 116 to spread the emitted light rays traveling into the area below. It can be seen that once the light rays 40, 42, 44 enter light tube 102, the rays 40, 42, 44 may reflect off the highly reflective inner walls 112 as the light travels downward, and generally “bounce” back and forth down the inner passageway of tube 102 until the rays 40, 42, 44 are emitted as diffused light 46 into the area below the ceiling. Note also however, that diffuser 108 may be removed and/or replaced by a lens that may instead focus the light rays as they exit light pipe 102. In this way, the light may be focused and perform as a spotlight. Other types of output lenses may also be used to affect the output light in different ways.

As described above, light tube assembly 100 may generally provide natural light to the area below the ceiling 30 during daylight hours. However, as sunlight wanes in the later portions of the day, the light transmitting through light tube 102 may begin to diminish. To solve this problem, light source 10 may include light engine assembly 200 that may provide artificial light when no natural light is available.

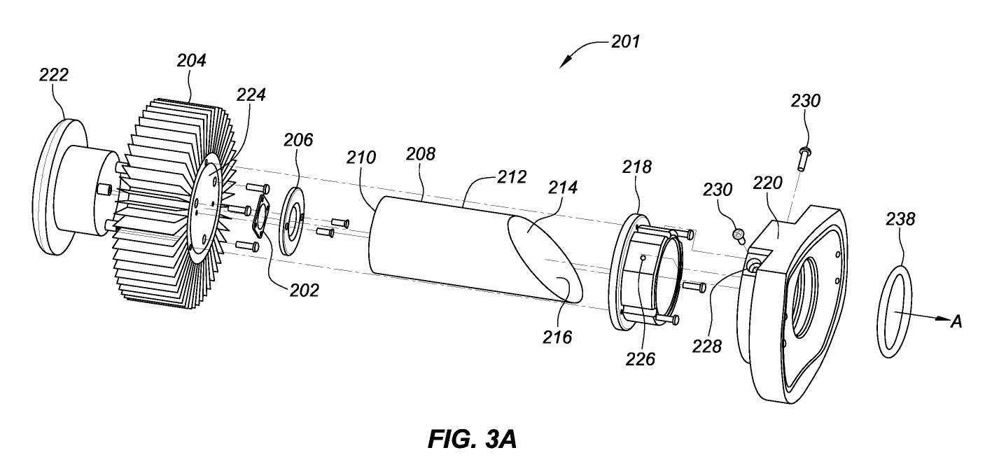

As depicted in FIG. 3A, light engine assembly 200 may include one or more light engines 201 that each may include LED 202. LED 202 may comprise one or more individual LEDs (such as Philips Lumiled Cool White COB, 5000K, 36V) mounted on a heatsink 204 (such as 70 W Spot Zhaga B3 Trido) via an LED holder 206 (such as Lumawise 250 Low Profile SH) or by other means. LED 202 may provide a high intensity output of white or colored light, and may generate a significant amount of heat that may be dissipated by heatsink 204. In this way, heat sink 204 may ensure that LED 202 remains within its nominal operating temperature to avoid damage or failure.

LED 202 may also be configured with lens 208 that may include an input 210, a body 212 and an output 214. LED 202 may be coupled with input 210 such that a maximum amount of light emitted by LED 202 may enter into input 210. In addition, the input 210 and output 214 surfaces of lens 208 may be highly polished to remove visible scratches, haze or other blemishes in order to meet industry standards (such as MIL-O-13830).

Once the light from LED 202 enters lens 208, the body 212 of lens 208 may generally guide the light forward through total internal reflection (TIR) to the output 214. Accordingly, lens 208 may or may not include an anti-reflective (AR) coating that may increase its internal reflection coefficient. As the light travels from the input 210 to the output 214 through body 212, the non-uniform light may be transformed to uniform (homogenized) light by the body 212 that may act as an optical waveguide, homogenizing rod or lightpipe. However, it should be noted that this may not be required depending on the length and other characteristics of lens 208, and that in any event, lens 208 may guide the light rays from its input 210 to its output 214.

The output 214 of lens 208 may be cleaved at an angle (for example, at 45 degrees) such that the light rays emitting from output 214 may be refracted at the interface between the cleaved surface 216 of output 214 and the outside environment, and may therefore emit at an angle with respect to axis A. In the example of output 214 being configured at a 45 degree angle as depicted in FIG. 3A, a portion of the light rays may generally emit from output 214 at a right angle with respect to axis A. The benefit of this is described in later sections.

The various components of light engines 201 may be configured together to form light engine 201 as follows. As shown in FIG. 3A, plug 222 may be inserted into the back of heat sink 204 and LED 202 may be secured to the front surface 224 of heat sink 204 via LED holder 206. These components may be secured together using screws or other means.

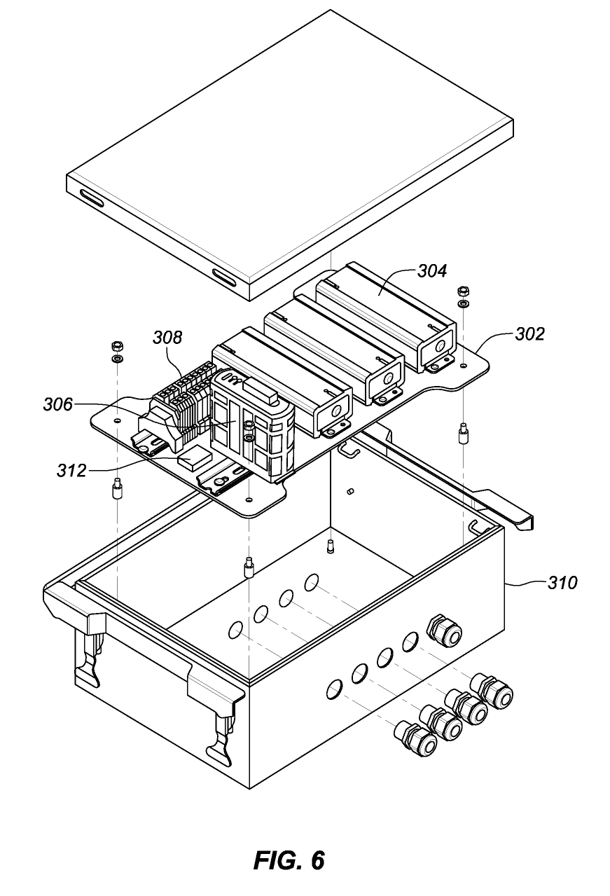

LED 202 may be attached to the front surface 224 of heat sink 204 with high thermal conductivity so that heat generated by LED 202 may be transferred into heat sink 204 and be dissipated into the environment via convection through its fins or other elements. In addition, plug 222 may have high thermal conductivity contact with heat sink 204 such it may also absorb heat and generally help to draw heat away from LED 202. LED holder 206 may be electrically configured with LED 202 so that the positive and negative leads on LED 202 necessary to provide LED 202 power may be electrically connected to the positive 236 and negative 234 leads on LED holder 206 (as shown in FIG. 7). The reason for this is described in later sections.

The input 210 of lens 208 may then be placed on the front of LED holder 206 to receive light from LED 202. In addition, collar 218 may include an inner opening such that it may slide over the body 212 of lens 208 and be attached to the front surface 224 of heat sink 204. These components may be attached using screws or other means. Lens mount 220 may also include an inner opening that may receive both the body of lens 208 and the front lip of collar 218. In this way, lens mount 220 may configured by sliding it over the body 212 of lens 208 and onto the front lip of collar 218. This may result in the front lip of collar 218 extending into the inner opening of lens mount 220, and the components may be attached using screws or other attachment means.

Collar 218 and lens mount 220 may include holes 226 and 228 respectively, and that these holes 226, 228 may align with each other when the components 218, 220 are configured as described above. Turning attention to FIGS. 3B and 3C, lens 208 may include at least one hole 224 that may extend into its circumferential surface as shown. It may be preferable that hole 204 extends a small amount into lens 208 (for example 3 mm) and that it not obstruct or compromise the lens's ability to guide the light as described above. The purpose of this hole 204 may be to secure lens 208 to collar 218 and lens mount 220.

With collar 218 and lens mount 220 configured and aligned, lens 208 may be aligned with each of these components such that hole 224 may also align with holes 226 and 228. In this way, screw 230 may be inserted to the combination of aligned holes 230 and 228 and into hole 224 of lens 208. Screw 230 may extend into hole 224 and that once in place it may be locked using pressure fit, a locking washer, glue or other locking mechanisms or means. While FIG. 3A depicts two holes 226 and 228, other numbers of holes may be used. In addition, lens 208 may include at least one or more holes 224 that may align with at least one or more holes 226 and 228 in order for lens 208 to be secured.

With LED 202, heat sink 204, LED holder 206, lens 208, collar 218, lens mount 220 and plug 222 configured together as described above, light engine 201 may be formed. And as shown in FIG. 3D, light engine 201 may thusly be a compact stand-alone component.

Moving forward, light engines 201 may be configured with light pipe assembly 100 such that they may provide artificial light from their LEDs 202 through their lenses 208 and into light pipe 202. The direction and orientation of the provided artificial light may allow for the light to travel downward through light tube 102 to exit diffuser 108 and be released into the area below.

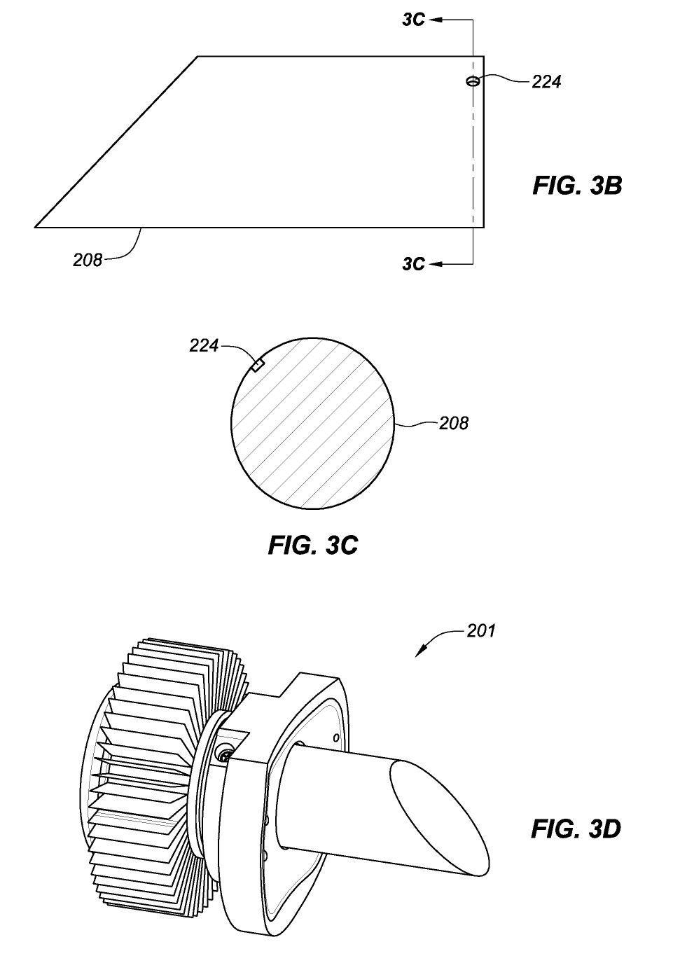

Specifically, as depicted in FIG. 4, light engines 201 may be configured to pass through openings 122 in the outer circumferential wall 118 of base 116 so that lens 208 may generally extend from outside base 116 to inside base 116. It may be preferable for the output 214 surface 216 of each lens 208 to be positioned entirely within the inside of base 116 so that most or all of its output light may be directed into base 116. FIG. 4 is a view looking into the bottom diffuser 108 of light tube 202. That is, it is a view looking upward into the output of light tube 202, and given this, it can be seen that each output 214 may be configured such that each cleaved output surface 216 may be generally positioned to face downwards and towards the output of light tube 202. In this way, light emitted out of outputs 214 may also be directed downward and out through the output diffuser 108 of light pipe 202.

Openings 122 may be slightly larger in diameter than the diameter of lens 208 such that each lens 208 may extend through each opening 122 with minimal gaps or spacing between the lens 208 and the opening 122. In addition, with lens 208 extending through openings 122 as described above, the front surface of lens mount 220 may be attached to the outer circumferential wall 118 of base 116 using screws or other attachment means. O-ring 238 may also be configured around lens 208 and between the front surface of lens mount 220 and the outer circumferential wall 118 of base 116. In this way, O-ring 238 may provide an air and water tight seal between the light engine 201 and the base 116.

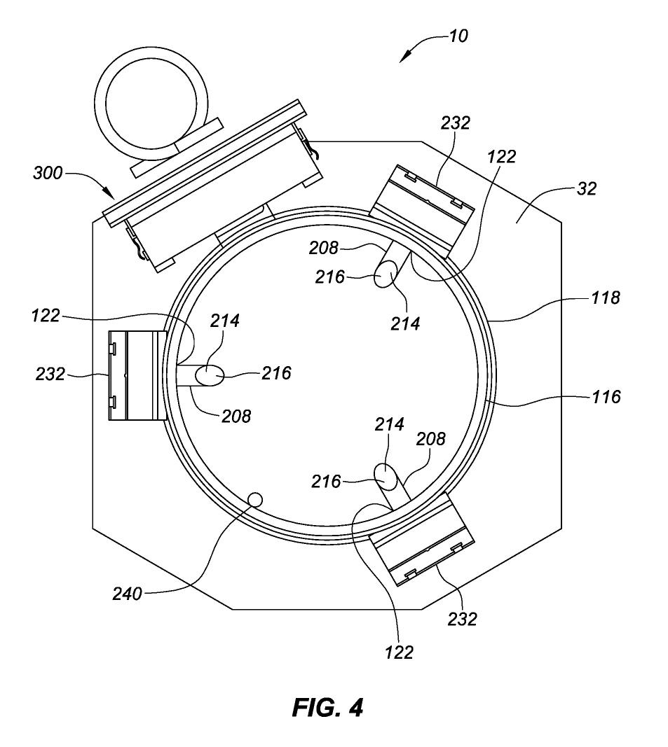

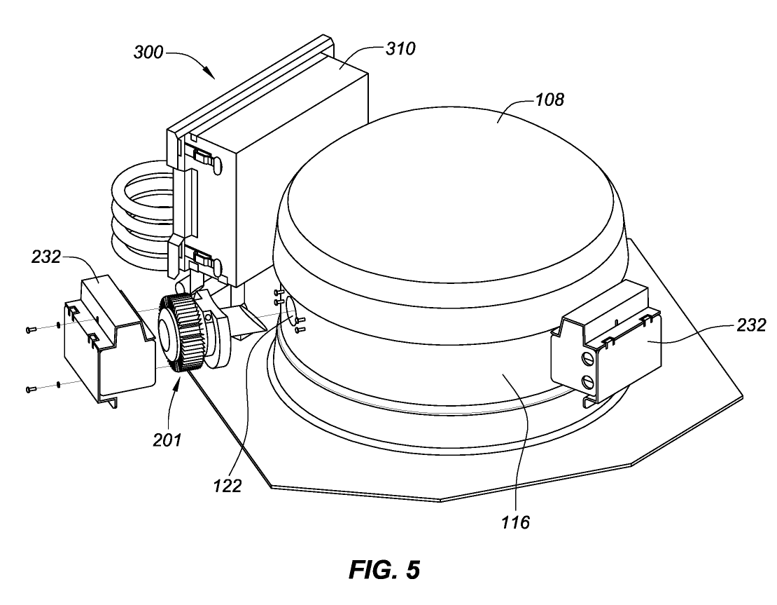

As shown in FIG. 4 and FIG. 5, each light engine 201 may also include vent cover 232 that may generally cover the portion of light engine 201 that may extend outward from circumferential wall 118 of base 116. Vent cover 232 may protect light engine 201 from damage from outside elements, and may also hide the light engine 201 from view. In addition, while FIG. 4 depicts the use of three light engines 201, other numbers of light engines 201 may be used with light source 10.

Also, as shown in FIG. 1 and FIG. 4, light engine assembly 200 may include light sensor 240 that may measure the amount of light that may be passing through light pipe 102. Light sensor 240 may be electrically configured with electronics assembly 300 (described below) and may provide continual feedback to the assembly 300. The purpose and benefits of light sensor 240 will be apparent after further discussion below. Note also that light sensor 240 may be located in other positions such as higher up in light pipe 102, at the top of light pipe 102, within top dome 104 or in other locations. In addition, more than one light sensor 240 may be used.

Moving forward, as depicted in FIG. 5, light source 10 may include electronics assembly 300 that may control and provide power to light engine assembly 200. Electronics assembly 300 may include one or more of the following components: standoff plate 302, LED driver 304, power supply 306, terminal block 308, microprocessor 312, as well as batteries, microcontrollers, integrated circuitry, and other electrical and non-electrical components and mechanisms that may be required to configure, control, maintain power and/or otherwise interact with light engines 201.

Electronics assembly 300 may also include enclosure 310 that may generally encompass, protect and hide the electronics from view. While FIG. 5 depicts electronics assembly 300 as positioned to the side of base 116, electronics assembly 300 may be positioned in other locations with respect to base 116. For example, electronics assembly 300 may be located in the area above ceiling 30 so that it may be out of view.

As mentioned above, LED holder 206 may be electrically configured with LED 202 so that its positive 236 and negative 234 leads may provide power to LED 202. Given this, as shown in FIG. 7, power source 306 of electronics assembly 300 may be electrically connected via wires or other electronic means to the positive 236 and negative 234 leads of LED holder 206 to provide it with power. In addition, control lines may also be configured between electronics assembly 300 and light engines 201 in the same or similar fashion. Note also that the wires that may be necessary to connect power source 306 with LED holder 206 may run along the outside or inside of base 116 and may be hidden from view. The wires may also be run in other locations.

Light source 10 may also include energy source assembly 400 that may provide power to electronics assembly 300 and to light engines 201. Energy source assembly 400 may comprise a variety of different types of power sources such as but not limited to 1) solar panels, 2) wind turbines and other types or combinations of types of power sources. Light source 10 may also receive power from local power grid to power light engines 201. In addition, energy source assembly 400 may include rechargeable battery packs 404 that may be charged to provide light engines 201 the power required.

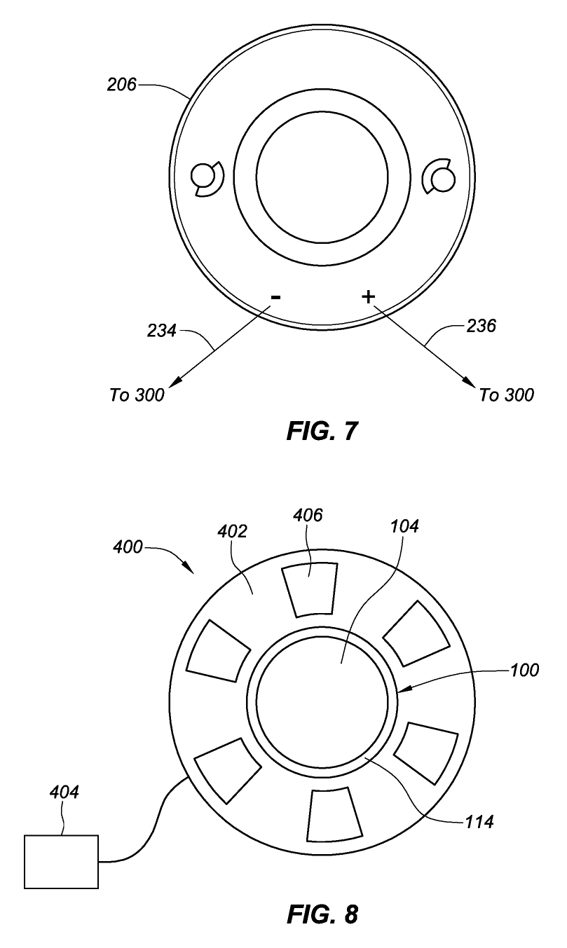

In one example as shown in FIG. 8, energy source assembly 400 may include solar panels 402 that may include photovoltaic cells 406 that may absorb sunlight, transform it to electricity and provide the electricity to rechargeable battery pack 404 for charging of the batteries 404. Solar panels 402 may be formed into a ring or donut-shape that may encircle the top input of light pipe 102 on the roof 20.

Battery pack 404 may be chosen to include enough rechargeable battery cells that may be charged to hold enough power to drive light engines 201 at an adequate intensity for an amount of time desired (for example, during non-daylight hours). Accordingly, battery pack 404 may include Lithium-ion, Lithium-ion polymer, Nickel-metal-hydride, Nickel-cadmium, Lead acid, or other types of rechargeable batteries. Other types of charge holding components such as capacitors, inductors or other types of components may also be used.

In addition, solar cells 406 preferably have a high efficiency in order to generate the amount of power necessary to charge battery pack 404 to provide the power required by light engines 201 as described above. Also, the number of solar cells 406 and the surface area that they may cover may be chosen to ensure that enough electricity may be generated by solar panels 402 to adequately charge battery pack 404.

This preferably allows for light source 10 to be fully sustainable in and of itself, twenty four hours a day, during daylight hours and non-daylight hours, without requiring or relying upon any outside sources of power. This is exceptionally good for the environment while providing a significant cost savings due to zero electrical bills.

During operation of light source 10, the general sequence of operations may be as follows:

1) During daylight hours, solar tube assembly 100 may collect and guide natural sunlight through light tube 102, and generally release it into the desired area.

2) In addition, during daylight hours, solar panels 402 may absorb sunlight, transform it to electricity and provide it to battery pack 404 to be charged.

3) As sunlight wanes during the late afternoon or early evening, light sensor 240 may sense the reduction of natural light and may trigger electronics assembly 300 to turn on and begin powering light engines 201. The intensity of light engines 201 may be controlled to gradually increase as the natural sunlight intensity decreases so that there may be a continual and constant intensity of light provided. Light sensor 240 may provide electronics assembly 300 with continual feedback (to microprocessor 312 for example) regarding the intensity of the natural light. In this way, light engines 201 may be controlled to emit only enough artificial light to add to and make up for the loss of the natural light. This control may be performed by microprocessor 312 or by other components. Accordingly, to people utilizing light source 10, there may be no noticeable transition between the times of operation when light source 10 emits natural light, when it emits a combination of natural light and artificial light from light engines 201, and when it emits only artificial light from light engines 201.

4) A similar sequence of operations may be performed for when weather conditions may impact the amount of natural light that may be available. For example, cloudy conditions may require light engines 201 to add light to the amount of natural light being provided. In this case, given feedback from light sensor 240, electronics assembly 300 may decrease, increase, or otherwise adjust the intensity of light engines 201 so that the output intensity from light source 10 may be constant even in during intermittent cloudy conditions.

5) As the sun rises in the morning and begins to provide natural light to solar tube assembly 100, or as cloudy conditions dissipate, sensor 240 may sense the return of natural light and may provide this feedback to electronics assembly 300. In this case, electronics assembly 300 may then begin to decrease the intensity of light engines 201 so that the total light output remains constant as the natural light increases. And once the natural light reaches a predetermined intensity such that light source 10 provides adequate lighting, electronics assembly 300 may turn off light engines 201 and await feedback from sensor 240 for when it may need to turn them back on.

The above sequence of operation is meant for demonstration purposes and the steps may be in different order, and other steps of operation may also be performed.

It is preferred that the above architecture of light source 10 including light pipe assembly 100, light engines assembly 200, electronic assembly 300 and power source assembly 400, may be a compact and self-contained source of light that may provide constant illumination throughout the day and night, completely independent from the building's electrical system. In addition, the integration of daytime and night time lighting solutions into a single compact unit provides for a simple and attractive ceiling installation.

In addition, light source 10 may be calibrated using light meters or other light reference standards that may measure the overall output of light source 10 during the different times of day and during different weather conditions. In this way, light engines 201 and light sensor 240 may be adjusted and generally calibrated together so that the output of light source 10 may be constant during all operating conditions.

As used herein, including in the claims, the phrase “based on” means “based in part on” or “based, at least in part on,” and is not exclusive. Thus, e.g., the phrase “based on factor X” means “based in part on factor X” or “based, at least in part, on factor X.” Unless specifically stated by use of the word “only,” the phase “based on X” does not mean “based only on X.”

Although certain presently preferred embodiments of the invention have been described herein, it will be apparent to those skilled in the art to which the invention pertains that variations and modifications of the described embodiments may be made without departing from the spirit and scope of the invention.

What is claimed is:

1. A lighting device, comprising:
a light tube that is configured to receive light from the sun and that includes an output; and
an artificial light source configured with the light tube;
wherein the light tube outputs light from the sun and/or light from the artificial light source.

2. The lighting device of claim 1, wherein the artificial light source comprises at least one LED with at least one lens.

3. The lighting device of claim 2, wherein the at least one lens provides light from the at least one LED into the light tube.

4. The lighting device of claim 1, further comprising at least one sensor configured to measure the intensity of the light received from the sun.

5. The lighting device of claim 4, wherein the intensity of the artificial light source is varied based on the measurements taken by the at least one sensor.

6. The lighting device of claim 5, wherein the light tube outputs light of constant intensity.

7. The lighting device of claim 1, further comprising at least one photovoltaic cell configured to receive light from the sun and at least one rechargeable power source configured to receive power from and be charged by the at least one photovoltaic cell.

8. The lighting device of claim 7, wherein the rechargeable power source provides power to the artificial light source.

9. A lighting device, comprising:
a light tube that is configured to receive light from the sun and that includes an output; and
an artificial light source configured with the light tube; and
at least one sensor configured to measure the intensity of the light received from the sun;
wherein the light tube outputs light from the sun and/or light from the artificial light source; and
wherein the intensity of the artificial light source is varied based on the measurements taken by the at least one sensor.

10. The lighting device of claim 9, wherein the artificial light source comprises at least one LED with at least one lens, and wherein the at least one lens provides light from the at least one LED into the light tube.

11. The lighting device of claim 9, wherein the light tube outputs light of constant intensity.

12. The lighting device of claim 9, further comprising at least one photovoltaic cell configured to receive light from the sun, and at least one rechargeable power source configured to receive power from and be charged by the at least one photovoltaic cell.

13. The lighting device of claim 12, wherein the rechargeable power source provides power to the artificial light source.

14. A lighting device, comprising:
a light tube that is configured to receive light from the sun and that includes an output; and
an artificial light source configured with the light tube;
at least one photovoltaic cell configured to receive light from the sun;
at least one rechargeable power source configured to receive power from and be charged by the at least one photovoltaic cell; and
at least one sensor configured to measure the intensity of the light received from the sun;
wherein the rechargeable power source provides power to the artificial light source;
wherein the intensity of the artificial light source is varied based on the measurements taken by the at least one sensor; and
wherein the light tube outputs light of a constant intensity comprising light from the sun and/or light from the artificial light source.

15. The lighting device of claim 14, wherein the artificial light source comprises at least one LED with at least one lens, and wherein the at least one lens injects light from the at least one LED into the light tube.

16. The lighting device of claim 15, wherein the at least one lens is cleaved.

17. The lighting device of claim 14, further comprising a controller that receives the measurements from the at least one sensor and that varies the intensity of the artificial light source based on the measurements.

18. The lighting device of claim 17, wherein the controller varies the intensity of the artificial light source resulting in the light tube outputting light of constant intensity.

19. The lighting device of claim 15, further comprising a heat sink configured with the at least one LED to cool the at least one LED.

20. The lighting device of claim 14, wherein the lighting device is independent of additional power sources.
